(19) United States
(12) Patent Application Publication
(10) Pub. No.: US 2017/0194567 A1
(43) Pub. Date: Jul. 6, 2017

(54) Organic Electronic Device and Method for the Production Thereof

(71) Applicant: COMMISSARIAT A L'ENERGIE ATOMIQUE ET AUX ENERGIES ALTERNATIVES, Paris (FR)

(72) Inventors: Solenn Berson, Chambery (FR); Stéphane Cros, Chambery (FR); Stéphane Guillerez, Lepin Le Lac (FR); Noëlla Lemaitre, Chambery (FR)

(73) Assignee: COMMISSARIAT A L'ENERGIE ATOMIQUE ET AUX ENERGIES ALTERNATIVES, Paris (FR)

(21) Appl. No.: 15/314,331

(22) PCT Filed: May 29, 2015
(86) PCT No.: PCT/FR2015/051421

§ 371 Date: Nov. 28, 2016

(30) Foreign Application Priority Data
Jun. 10, 2014 (FR) 1455221

(51) Int. Cl. H01L 51/00

(52) U.S. Cl. CPC H01L 51/0037; H01L 51/0003; H01L 51/0026; H01L 51/0035; H01L 51/0036; H01L 51/0047; H01L 51/004; H01L 51/0046; H01L 51/5064

(57) ABSTRACT

An organic electronic device containing a stack successively including a polymer substrate covered with a first layer E1 made of conductive or semiconductor material; a hole transport layer HTL; an active layer A; and a second layer E2 made of conductive or semiconductor material. The HTL layer is a bilayer formed of a so-called neutral layer based on PEDOT:PSS and of a so-called acid layer based on PEDOT:PSS. The neutral layer is in contact with first layer E1 while the acid layer is in contact with active layer A.

### TECHNOLOGICAL FIELD

The present description relates to the field of organic electronic devices, such as organic photovoltaic cells, organic light-emitting diodes (OLED), and organic photodetectors (OPD). It relates, in particular, to an organic electronic device comprising a bilayer HTL layer formed of a so-called neutral layer based on PEDOT:PSS and of a so-called acid layer based on PEDOT:PSS.

### BACKGROUND

The development of alternatives to fossil energies is a major issue, be it from an environmental or economical point of view.

Photovoltaic devices enable to convert solar energy into electrical energy, which makes them particularly attractive. However, they exhibit conversion efficiencies and a lifetime which limit their field of application.

Generally, a so-called conventional photovoltaic cell comprises a stack formed of (FIG. 1):

a substrate (1) covered with a first conductive layer (2) (anode);

an HTL layer (3);

an active layer (4);

possibly an ETL layer (“electron transporting layer”)

and a second conductive layer (5) (cathode).

Such a cell may also be called PIN stack.

The substrate (1) may be made of plastic or of glass, for example.

The first conductive layer (2) forming the anode may be made of conductive metal oxide, for example, of ITO (indium tin oxide), AZO (aluminum zinc oxide), IZO (indium zinc oxide). It may also appear in the form of a multilayer of AZO/Ag/AZO type, for example.

The HTL layer (3), interposed between the anode (2) and the active layer (4) is a hole transport layer (HTL). It is a p-type conductive or semiconductor layer which is generally made of PEDOT:PSS (poly(3,4-ethylenedioxythiophene):poly(4-styrene-sulfonate)) conductive polymer.

The active layer (4) is a layer intended to absorb photons. It enables to create free charge carriers (holes and electrons). It may be of polymer type, particularly made of P3HT/PCBM, that is, made of the mixture of the poly(3-hexylthiophene) and [6,6]-phenyl-C₆₁-butyric acid methyl ester compounds.

Finally, the second conductive layer (5), that is, the cathode, may be made of metal, particularly of aluminum or of silver.

This type of stack has certain disadvantages, particularly due to the interface between the active layer (4) and the electrodes (2) and (5).

The HTL layer (3) forms the interface on the anode side. As already indicated, it is generally made of PEDOT:PSS. Now, the high density of sulfonate groups on the PSS chains, as compared with the density of positive charges on the PEDOT chains, causes an increase in the acidity of the HTL layer.

The acidity of the PEDOT:PSS HTL layer, as well as the acidity of the PEDOT:PSS solution used to form said layer may damage the anode (2) (particularly made of conductive metal oxide). This is especially true when the substrate is made of plastic. Indeed, the conductive metal oxide deposited on the plastic substrate to form the anode (2) cannot be annealed at a high temperature due to the nature of the substrate. Accordingly, the structure of the layer forming the anode (2) is more brittle and is a weak point of this type of photovoltaic cell.

Since the conventional PEDOT:PSS structure is a major source of the degradation of prior art photovoltaic cells, neutralized PEDOT:PSS solutions have been developed. Even if they ease the implementation, they are not fully satisfactory. Indeed, the devices obtained from such neutralized solutions also degrade along time and during the manufacturing.

As an example, document WO2007/031923 describes a light-emitting device, where part of the acid groups of the PSS of the buffer PEDOT:PSS layer is esterified. The esterification is performed after the deposition of the PEDOT:PSS layer on the anode. This is a surface treatment. The esterified, that is, neutral, layer portion is thus in contact with the active layer to avoid inhibiting the luminescence.

The organic electronic device according to the presently described embodiments enables to overcome the performance degradation, particularly along time and in operation.

### SUMMARY OF THE SPECIFICATION

The Applicant has developed an organic electronic device having a structure enabling to improve the lifetime with respect to similar prior art devices. The device comprises an HTL layer based on PEDOT:PSS, specific to the interface between the anode and the active layer.

The specific HTL layer enables to combine the resulting advantages of an HTL Layer formed from an acid composition/solution based on PEDOT:PSS, without for all this embrittling the layer of conductive or semiconductor material in contact with the substrate.

More particularly, the presently described embodiments relate to an organic electronic device containing a stack successively comprising the following layers:

a polymer substrate covered with a first layer E1 made of conductive or semiconductor material;

a hole transport layer HTL;

an active layer A;

a second layer E2 made of conductive or semiconductor material.

According to the presently described embodiments, the HTL layer is a bilayer formed of a so-called neutral layer based on PEDOT:PSS and of a so-called acid layer based on PEDOT:PSS.

According to a specific embodiment, the HTL layer is a bilayer formed of a so-called neutral PEDOT:PSS layer and of a so-called acid PEDOT:PSS layer.

It is an organic electronic device having a conventional configuration where said so-called acid HTL layer in contact with active layer A, and said so-called neutral HTL layer is in contact with first layer E1. Due to this layout, first layer E1 is not degraded by the acidity of the HTL layer based on PEDOT:PSS.

The organic electronic device comprises a stack of layers on a polymer substrate, particularly made of plastic. The polymer substrate may advantageously be made of a material selected from the group comprising polyethylene naphthalate (PEN); polyethylene terephthalate (PET); cyclic olefin copolymers (COC); polyimides such as Kapton®, in particular.

Further, the polymer substrate has a thickness advantageously in the range from 50 micrometers and 200 micrometers.

The organic electronic device also comprises a first layer E1 made of conductive or semiconductor material. Layer E1 is advantageously in contact with the polymer substrate. It is advantageously deposited on the polymer substrate.

This conductive or semiconductor material forming first layer E1 may advantageously be selected from the group comprising conductive or semiconductor metal oxides. It may in particular be ITO (indium tin oxide), AZO (aluminum zinc oxide), IZO (indium zinc oxide); GZO (gallium zinc oxide).

First layer E1 may also appear in the form of a multilayer of AZO/Ag/AZO type, for example, or IZO/Ag/IZO.

Advantageously, first layer E1 forms the anode of the organic electronic device.

First layer E1 is advantageously in contact with the HTL layer, which is a hole transport layer.

Typically, layer E1 has a thickness advantageously in the range from 100 to 500 nanometers.

As already indicated, the HTL layer is formed of a stack of two superposed layers, respectively formed of a so-called neutral HTL layer and of a so-called acid HTL layer, the two layers being made of PEDOT:PSS.

The mixture of PEDOT:PSS polymers advantageously appears in the form of a colloidal solution. The adjustment of the pH of this mixture thus enables to deposit each of the so-called neutral and acid PEDOT:PSS layers.

So-called neutral HTL layer means that the PEDOT:PSS layer of the stack has been formed from a composition or a neutralized solution based on PEDOT:PSS. In other words, the so-called neutral HTL layer is formed from a composition or solution based on PEDOT:PSS having a pH greater than or equal to 5, and more advantageously a pH in the range from 5 to 8 and preferably from 5 to 7.

The layer thus formed is then made of PEDOT:PSS with, preferably counter-ions of NH₄⁺, primary ammonium RNH₃⁺, secondary ammonium R¹R²NH₂⁺, tertiary ammonium R¹R²RHN⁺, quaternary ammonium R¹R²R³R⁴N⁺, Na⁺, or K⁺ type.

So-called acid HTL layer means that the PEDOT:PSS layer of the stack has been formed from an acid composition or solution based on PEDOT:PSS. In other words, the so-called acid HTL layer is formed from a composition or solution based on PEDOT:PSS having a pH smaller than 5, and more advantageously a pH in the range from 1 to 3.

The layer thus formed is then made of PEDOT:PSS with, preferably, H⁺ counter-ions.

Typically, the neutral HTL layer has a thickness advantageously in the range from 10 to 40 nanometers.

Typically, the acid HTL layer has a thickness advantageously in the range from 10 to 100 nanometers.

The HTL layer formed of the neutral and acid layers has a thickness advantageously in the range from 20 to 110 nanometers, more advantageously from 30 to 60 nanometers.

The organic electronic device also comprises an active layer A.

Generally, active layer A is based on organic molecules or on polymer. It may also be based on a metal-organic compound, advantageously, a halogen metal-organic compound.

It may in particular be made of a mixture of derivatives of polythiophenes (p-type polymer), particularly poly(3-hexylthiophene) (P3HT), and of derivatives of fullerene (as n-type acceptors), particularly [6,6]-phenyl-C₆₁-butyric acid methyl ester (PCBM).

Advantageously, it is made of the P3HT/PCBM mixture.

Typically, active layer A has a thickness advantageously in the range from 80 to 500 nanometers, and more advantageously still in the range from 200 to 500 nanometers.

The organic electronic device also comprises a second layer E2 made of conductive or semiconductor material. Layer E2 is advantageously in contact with the active layer. It is advantageously deposited on the active layer.

The conductive or semiconductor material forming second layer E2 may advantageously be selected from the group comprising Ca, Al, Ag, Cu, the C60/LiF/Mn/Al stack or the ETL/Ag bilayer, with, in particular, TiOₓ or ZnO for the ETL layer (“electronic transporting layer”).

Advantageously, second layer E2 forms the cathode of the organic electronic device.

According to a specific embodiment, the nature of the polymer substrate and the thickness of the layers forming it enable the organic electronic device to have flexibility properties.

The presently described embodiments also relate to a method of preparing the above-described organic electronic device. The method comprises the steps of:

providing a polymer substrate covered with a first layer E1 of conductive or semiconductor material;

forming a neutral HTL layer on first layer E1, from a composition based on PEDOT: PSS having a pH greater than or equal to 5, advantageously between 5 and 8 and more advantageously between 5 and 7;

forming an acid HTL layer on the neutral HTL layer, from a composition based on PEDOT:PSS having a pH smaller than 5, advantageously between 1 and 3;

forming an active layer A on the acid HTL layer;

forming a second layer E2 of conductive or semiconductor material on active layer A.

First layer E1 is deposited according to conventional techniques within the general knowledge of those skilled in the art.

The acid HTL layer and the neutral HTL layer are deposited from a composition of an HTL layer material. Such depositions are advantageously carried out by wet process. The implemented technique may in particular be selected from the group comprising spin coating; printing; coating; inkjet; slot dye; silk-screening; photogravure; and flexogravure.

Advantageously, the neutral HTL layer is formed by wet deposition, followed by an anneal.

Still advantageously, the acid HTL layer is formed by wet deposition, followed by an anneal.

The anneal of the neutral HTL layer is advantageously carried out at a temperature in the range from 80 to 140° C. The duration of this anneal is advantageously in the range from 1 minute to 1 hour.

The anneal of the neutral HTL layer is advantageously carried out under vacuum, typically between 1 and 5 mbar.

The anneal of the neutral HTL layer particularly enables to avoid the dissolution of the neutral HTL layer during the subsequent deposition of the acid HTL layer.

The anneal of the acid HTL layer is advantageously carried out at a temperature in the range from 80 to 140° C. The duration of this anneal is advantageously in the range from 1 minute to 30 minutes.

The anneal of the acid HTL layer is advantageously carried out under vacuum.

According to a specific embodiment, it may be followed by a second anneal.

The second anneal of the acid HTL layer is advantageously carried out at a temperature in the range from 80 to 140° C. The duration of this anneal is advantageously in the range from 1 to 5 minutes.

The second anneal of the acid HTL layer is advantageously carried out under air.

The optional anneal of active layer A is advantageously carried out at a temperature greater than 50° C., and more advantageously in the range from 50° C. to 140° C. The duration of this anneal is advantageously in the range from 1 minute to 30 minutes.

Second layer E2 is then deposited according to conventional techniques within the general knowledge of those skilled in the art.

Generally, the conditions of the different anneal steps are compatible with the nature of the polymer substrate. The temperature and the duration of the anneals are thus accordingly adjusted.

The organic electronic device described hereabove may be an organic photovoltaic cell (OPV); an organic photodiode (OPD) or an organic light-emitting diode (OLED).

During the use of the organic electronic device, particularly in the case of a photovoltaic cell, the surface corresponding to the polymer substrate is exposed to the incident radiation.

The contemplated embodiments and the resulting advantages will better appear from the following non-limiting drawings and examples, provided as an illustration.

### BRIEF DESCRIPTION OF THE DRAWINGS

FIG. 1 illustrates a conventional OPV-type photovoltaic cell.

FIG. 2 illustrates the HTL hole transport layer.

FIG. 3 corresponds to the efficiency of conversion of solar energy into electrical energy for photovoltaic cells deposited on a glass substrate.

FIG. 4 corresponds to the efficiency of conversion of solar energy into electrical energy for photovoltaic cells deposited on a plastic substrate.

FIG. 5 illustrates a specific embodiment of photovoltaic cell.

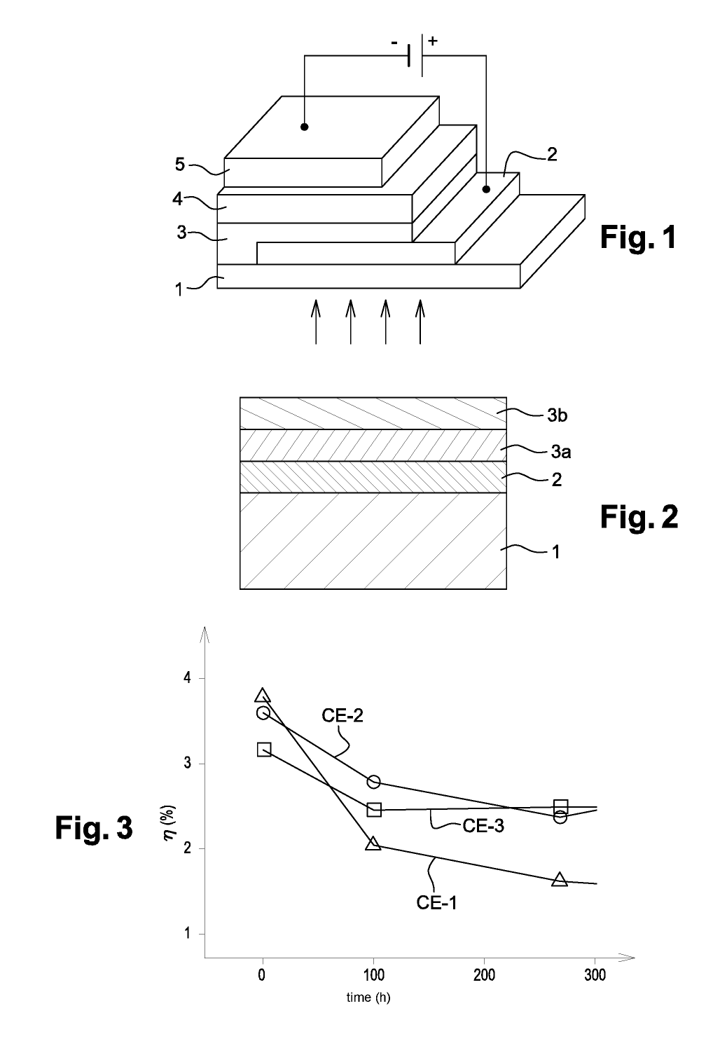

### DETAILED DESCRIPTION

The organic electronic device contemplated herein may comprise the stack shown in FIG. 2, that is, at least:

a polymer substrate (1);

a first layer E1 (2) of conductive or semiconductor material on polymer substrate S;

a neutral hole transport HTL layer (3a) on first layer E1;

an acid hole transport HTL layer (3b) on the neutral HTL layer.

In addition to this stack, the organic electronic device (photovoltaic cell) also comprises an active layer A and a second layer E2 of conductive or semiconductor material on the acid HTL layer.

Advantageously, first layer E1 and second layer E2 respectively form the electrodes of the organic electronic device and particularly the anode and the cathode in the case of a photovoltaic cell.

In addition to these layers, the organic electronic device may also comprise additional layers which may be interleaved.

As an example, a specific embodiment shows as an alternative embodiment a tandem-type organic photovoltaic cell with the stack illustrated in FIG. 5.

The stack successively comprises:

a polymer substrate (1);

a layer (2) of metal oxide forming the anode;

a layer of P-type material (6);

an active layer A (4);

a layer of N-type material (7);

a neutral HTL layer (3a);

an acid HTL layer (3b);

an active layer A (4);

a layer of N-type material (8);

a layer E forming an electrode (5).

### EMBODIMENTS

Six organic electronic devices (photovoltaic cells) having the following characteristics have been prepared:

| Example | substrate | anode | HTL layer | active layer | cathode |
|---|---|---|---|---|---|
| CE-1 | glass | ITO | PEDOT:PSS | P3HT/PCBM | C60/LiF/Mn/Al |
| | | | N | | |
| CE-2 | glass | ITO | PEDOT:PSS | P3HT/PCBM | C60/LiF/Mn/Al |
| | | | A | | |
| CE-3 | glass | ITO | PEDOT:PSS | P3HT/PCBM | C60/LiF/Mn/Al |
| | | | N + A | | |
| CE-4 | PET | ITO | PEDOT:PSS | P3HT/PCBM | C60/LiF/Mn/Al |
| | | | N | | |
| CE-5 | PET | ITO | PEDOT:PSS | P3HT/PCBM | C60/LiF/Mn/Al |
| | | | A | | |
| INV-1 | PET | ITO | PEDOT:PSS | P3HT/PCBM | C60/LiF/Mn/Al |
| | | | N + A | | |

PET = polyethylene terephthalate
ITO = indium tin oxide
PEDOT:PSS N = aqueous dispersion based on the mixture of poly(3,4-ethylenedioxythiophene) and of neutral sodium poly(styrene sulfonate) commercialized under trade name Clevios ™ P jet N by Héraeus and having a pH in the range from 5 to 8
PEDOT:PSS A = aqueous dispersion based on the mixture of poly(3,4-ethylenedioxythiophene) and of acid sodium poly(styrene sulfonate) commercialized under trade name Clevios ™ PH by Héraeus and having a pH in the range from 1.5 to 2.5
PEDOT:PSS N + A = a layer of neutral PEDOT:PSS + a layer of acid PEDOT:PSS
P3HT/PCBM = poly(3-hexylthiophene)/[6,6]-phenyl-C₆₁-butyric acid methyl ester, with a 1/1 mass ratio

### Embodiment

Deposition on glass:

An ITO layer is formed on a glass substrate.

The HTL layer (N or A) is formed as follows:

A composition of neutral or acid PEDOT:PSS is deposited on the ITO layer, by spin coating to obtain an HTL layer having a 45-nanometer thickness.

The HTL layer thus obtained is annealed in an oven, for 30 minutes at 180° C. and under air.

HTL layer N+A (bilayer) is formed as follows:

A neutral composition of PEDOT:PSS is deposited on the glass substrate by spin coating, to obtain a 25-nanometer layer.

The HTL layer N thus obtained is annealed in an oven, for 30 minutes at 180° C. and under air.

A 20-nanometer layer of PEDOT:PSS A is deposited from a solution of PEDOT:PSS A diluted by 50% in water.

The HTL layer N+A thus obtained is annealed in an oven, for 30 minutes at 180° C. and under air.

The active layer, made of P3HT:PCBM (mass ratio 1:1), is deposited on the HTL layer (N, A, or N+A) by spin coating in an inert atmosphere (glove box) to obtain a 200-nanometer thickness.

An anneal for 10 minutes at 140° C. is then carried out on a hot plate in an inert atmosphere (glove box).

The C60 (2 nm)/LiF (1 nm)/Mn (10 nm)/A1 (200 nm) cathode is formed by vacuum evaporation.

Deposition on PET:

An ITO layer is formed on the PET substrate.

The HTL layer (N or A) is formed as follows:

A composition of neutral or acid PEDOT:PSS is deposited on the ITO layer, by spin coating to obtain an HTL layer having a 45-nanometer thickness.

The HTL layer thus obtained is annealed in a vacuum oven, for one night at 80° C. It is then annealed for 5 minutes at 120° C. on a hot plate under air.

HTL layer N+A (bilayer) is formed as follows:

A composition of neutral PEDOT:PSS is deposited on the PET substrate by spin coating, to obtain a 25-nanometer layer.

The HTL layer N thus obtained is annealed in a vacuum oven for 15 minutes at 80° C.

A 20-nanometer layer of PEDOT:PSS A is deposited from a solution of PEDOT:PSS A diluted by 50% in water.

The HTL layer N+A thus obtained is annealed in a vacuum oven, for one night at 80° C. An anneal for 5 minutes at 120° C. is then carried out on a hot plate under air.

The active layer, made of P3HT: :PCBM (mass ratio 1:1), is deposited on the HTL layer (N, A, or N+A) by spin coating in an inert atmosphere (glove box) to obtain a 200-nanometer thickness.

An anneal for 10 minutes at 120° C. is then carried out on a hot plate in an inert atmosphere (glove box).

The C60 (2 nm)/LiF (1 nm)/Mn (10 nm)/A1 (200 nm) cathode is formed by vacuum evaporation.

Lifetime test results:

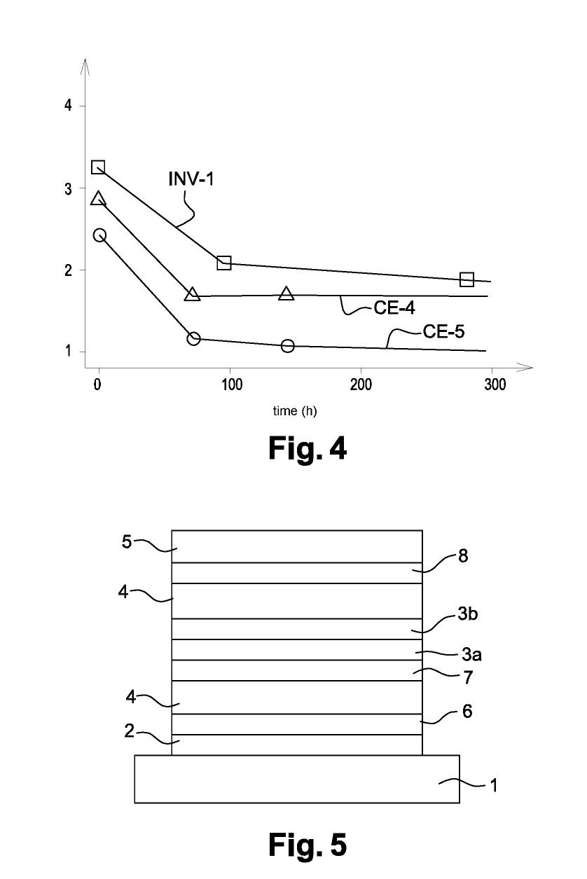

The lifetime of the photovoltaic cells according to examples CE-1 to CE-5 and INV-1 has been tested. The graphs of FIGS. 3 and 4 correspond to measurements at t=0 and then, after aging under an AM 1.5, 100 mW/cm² illumination at 40 ° C., under ambient relative humidity conditions. The aging corresponds to standard illumination conditions.

The tests show:

on the glass substrate (FIG. 3): an accelerated degradation of the cell having a neutral HTL layer (CE-1) as compared with the cell having an acid HTL layer (CE-2).

on the PET substrate (FIG. 4): a marked degradation of the cells having an acid (CE-5) or neutral (CE-4) HTL layer as compared with the cell having an acid+neutral HTL layer (N+A) (INV-1).

The neutral HTL layer induces an accelerated aging due to a specific problem at the interface with the active layer (this problem being common to both types of substrate). The acid HTL layer induces a specific problem at the interface with the plastic substrate ITO (PET).

The use of an HTL layer N+A enables to obtain performances and a stability generally greater than for a structure only comprising a neutral HTL layer (CE-4) and significantly greater than for a structure only comprising an acid HTL layer (CE-5).

1. An organic electronic device containing a stack successively comprising the following layers:
a polymer substrate covered with a first layer E1 made of conductive or semiconductor material;
a hole transport layer HTL;
an active layer A;
a second layer E2 made of conductive or semiconductor material;
wherein the HTL layer is a bilayer formed of:
a so-called neutral layer based on PEDOT:PSS, which is in contact with first layer E1; and
a so-called acid layer based on PEDOT:PSS, which is in contact with active layer A.

2. The device according to claim 1, wherein the so-called neutral PEDOT:PSS layer is made from a composition based on PEDOT:PSS having a pH greater than or equal to 5 and preferably in the range from 5 to 8;
and wherein the so-called acid PEDOT:PSS layer is made from a composition based on PEDOT:PSS having a pH smaller than 5 and preferably in the range from 1 to 3.

3. The device according to claim 1, wherein the so-called neutral PEDOT:PSS layer comprises counter-ions of NH₄⁺, RNH₃⁺, R¹R²NH₂⁺, R¹R²R³HN³⁰ , R¹R²R³R⁴N+, Na⁺, or K⁺ type;
and wherein the so-called acid PEDOT:PSS layer comprises H⁺-type counterions.

4. The device according to claim 1, wherein the HTL layer is a bilayer formed of a so-called neutral PEDOT:PSS layer and of a so-called acid PEDOT:PSS layer.

5. The device according to claim 1:
wherein the neutral HTL layer has a thickness advantageously in the range from 10 to 40 nanometers; and
wherein the acid HTL layer has a thickness advantageously in the range from 10 to 100 nanometers.

6. The device according to claim 1, wherein the polymer substrate is made of a material selected from the group comprising polyethylene naphthalate; polyethylene terephthalate; cyclic olefin copolymers; and polyimide.

7. The device according to claim 1, wherein first layer E1 is made of a conductive or semiconductor material selected from the group comprising ITO (indium tin oxide); AZO (aluminum zinc oxide); IZO (indium zinc oxide); and GZO (gallium zinc oxide).

8. The device according to claim 1, wherein active layer A is made of the mixture of poly(3-hexylthiophene) and [6,6]-phenyl-C₆₁-butyric acid methyl ester.

9. The device according to claim 1, wherein the device is an organic photovoltaic cell; an organic photodiode or an organic light-emitting diode.

10. A method of preparing an organic electronic device containing a stack successively comprising (i) a polymer substrate covered with a first layer E1 made of conductive or semiconductor material; (ii) a hole transport layer HTL; (iii) an active layer A; and (iv) a second layer E2 made of conductive or semiconductor material, wherein the HTL layer is a bilayer formed of: (i) a so-called neutral layer based on PEDOT:PSS, which is in contact with first layer E1; and (ii) a so-called acid layer based on PEDOT:PSS, which is in contact with active layer A, the method comprising the steps of:
providing a polymer substrate covered with a first layer E1 of conductive or semiconductor material;
forming a neutral HTL layer on first layer E1, from a composition based on PEDOT: PSS having a pH greater than or equal to 5;
forming an acid HTL layer on the neutral HTL layer, from a composition based on PEDOT:PSS having a pH smaller than 5;
forming an active layer A on the acid HTL layer;
forming a second layer E2 of conductive or semiconductor material on active layer A.

11. The method according to claim 10, wherein the acid HTL layer and the neutral HTL layer are formed by wet deposition, followed by an anneal.

12. The method according to claim 10, wherein the acid HTL layer and the neutral HTL layer are formed by wet deposition by a technique selected from the group comprising spin coating; printing; coating;
inkjet; slot dye; silk-screening; photogravure; and flexogravure.

13. The method according to claim 10:
wherein the anneal of the neutral HTL layer is carried out under vacuum at a temperature in the range from 80 to 140° C.; and
wherein the anneal of the acid HTL layer is carried out under vacuum at a temperature in the range from 80 to 140° C.

14. The method according to claim 10, wherein the forming of the neutral HTL layer on first layer E1 is carried out from a composition based on PEDOT: PSS having a pH in the range from 5 to 8.

15. The method according to claim 10, wherein the forming of the acid HTL layer on the neutral HTL layer is carried out from a composition based on PEDOT:PSS having a pH in the range from 1 to 3.
